(19) United States
(12) Patent Application Publication
(10) Pub. No.: US 2004/0063321 A1
(43) Pub. Date: Apr. 1, 2004

(54) Method for fabricating a semiconductor configuration

(76) Inventors: Bernd Goebel, Dresden (DE); Peter Moll, Dresden (DE); Harald Seidl, Feldkirchen (DE); Martin Gutsche, Dorfen (DE)

Correspondence Address: LERNER AND GREENBERG, P.A., POST OFFICE BOX 2480, HOLLYWOOD, FL, 33022-2480, US

(21) Appl. No.: 10/675,766

(22) Filed: Sep. 30, 2003

Related U.S. Application Data
(63) Continuation of application No. PCT/EP02/03344, filed on Mar. 25, 2002.

(30) Foreign Application Priority Data
Mar. 30, 2001 (DE) 101 15 912.9

(51) Int. Cl. H01L 21/302; H01L 21/461

(52) U.S. Cl. 438/689

(57) ABSTRACT

A known lithographic method is used to remove a thin mask layer, particularly a Si₃N₄ liner, on one side of a depression in a semiconductor configuration having a depression. An ion beam is directed obliquely onto the depression at an angle, which removes the thin mask layer in irradiated regions.

### CROSS-REFERENCE TO RELATED APPLICATION

This application is a continuation of copending International Application No. PCT/EP02/03344, filed Mar. 25, 2002, which designated the United States and was not published in English.

### BACKGROUND OF THE INVENTION

1. Field of the Invention

The present invention relates in particular to a method for fabricating a semiconductor configuration.

Semiconductor configurations for DRAMs in sub-μ technology with a deep trench (DT) capacitor and a selection transistor are known on the basis of the prior art from the reference by D. Widmann, H. Mader, H. Friedrich, entitled: Technologie hochintegrierter Schaltungen [Technology of Large-Scale Integrated Circuits]—2^{nd} edition—Springer, 1996, inter alia. To be able to connect the DT capacitor to the selection transistor, the DT capacitor needs to be able to be conductively connected to the substrate. The contact or the connection (buried strap or buried contact) may exist only on the side facing the associated selection transistor below the mono-silicon surface, however. For this reason, the insulation between the DT capacitor and the selection transistor or the substrate needs to be removed on the side and replaced with a conductive material. By contrast, no conductive connection may be produced on the other side of the DT capacitor. Conversely, it is also possible to remove an existing conductive connection between the DT capacitor and the substrate on one of the two sides and thereby to produce the buried strap. In principle, the two sides of the DT capacitor therefore need to be handled differently. This problem is solved in accordance with the prior art by a lithographical method in which only one side of the DT capacitor is covered, with a subsequent etching operation removing the buried strap on the areas that are not covered (see Widmann, Mader: p. 339; step 11).

In addition, Widmann et al. disclose the practice of also making use of vertical surfaces during patterning in trenches, for example using process steps such as defined back etching and oblique implantation (see Widmann: Mader: pp. 82, 178, 282). By way of example, oblique implantation at an irradiation angle of approximately 45° through a spacer is known in order to produce short lightly doped drain (LDD) doping profiles.

U.S. Pat. No. 5,240,875 discloses a method for patterning an oxide layer in a depression in a semiconductor substrate using oblique ion bombardment in order to vary the layer thickness of the oxide layer in the depression.

U.S. Pat. No. 4,958,206 describes a method for producing a buried strap contact for a deep trench capacitor on a silicon wafer.

### SUMMARY OF THE INVENTION

It is accordingly an object of the invention to provide a method for fabricating a semiconductor configuration that overcomes the above-mentioned disadvantages of the prior art methods of this general type, which can be used to produce a buried strap contact for a deep trench capacitor simply and reliably.

With the foregoing and other objects in view there is provided, in accordance with the invention, a method for producing a buried strap contact in a trench capacitor having a polysilicon core and a collar oxide surrounding the polysilicon core. The method includes providing a silicon substrate having a depression formed therein, the trench capacitor with the polysilicon core and the collar oxide are disposed in the depression. A mask layer is introduced into the depression. The mask layer is patterned with an ion beam being directed obliquely onto the depression at an angle for irradiating the mask layer only in an irradiated subregion of the depression resulting in a removal of the mask layer in the irradiated subregion. The collar oxide is partially exposed during the irradiating step. Exposed areas of the collar oxide are back etched along the polysilicon core using the mask layer as an etching mask resulting in a back etched collar oxide. A polysilicon layer is formed in a region of the back etched collar oxide to produce the buried strap contact for the polysilicon core of the trench capacitor.

The ion beam directed obliquely onto the wafer surface at the irradiation angle α uses the geometry of the hole or depression. Since the unwanted ion attack on a sidewall surface is prevented by the shadowing effect in the depression, the layer can be removed on one side, reproducibly and with sufficient accuracy, over the entire surface of the wafer in one method step. In contrast to the known lithographic methods, however, the inventive method is not dependent on the precise relative positioning and alignment of two lithography planes with respect to one another, which also becomes more and more complex with smaller pattern sizes. The inventive method is instead self-aligning and independent of lithographical alignment accuracies. A similar situation applies to the use of an ion beam system for carrying out the method and to a semiconductor configuration fabricated using the inventive method.

If all the depressions in the semiconductor configuration on a wafer, which are intended to hold buried straps, have a standard geometry, the invention makes it a simple matter to remove the liner on one side in the depression reproducibly and accurately and then to produce the buried strap.

Advantageously, the ion beam is generated by a relatively swivellable reactive ion beam etching (RIBE) source. This ensures controlled selective etching of the liner at a good etching rate.

In accordance with an added mode of the invention, there is the step of etching away part of the collar oxide from a top of the polysilicon core in the depression before performing the introducing step.

In accordance with another mode of the invention, there is the step of forming the mask layer with a top liner layer and a bottom liner layer, and the ion beam patterns the top liner layer. A pattern of the top liner layer is then transferred to the bottom liner layer with an etching process.

In accordance with a further mode of the invention, there is the step of forming the collar oxide to cover sidewalls of the depression and the ion beam patterns the mask layer such that the mask layer is removed on a side wall of the depression at least down to a level above a top of the polysilicon core which corresponds to a width of the collar oxide.

In accordance with another mode of the invention, there is the step of depositing a Si₃N₄ layer having a thickness of approximately 5-10 nm into the depression for forming the mask layer to be patterned by the ion beam.

Other features which are considered as characteristic for the invention are set forth in the appended claims.

Although the invention is illustrated and described herein as embodied in a method for fabricating a semiconductor configuration, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE DRAWINGS

FIGS. 1A-1F are diagrammatic, sectional views illustrating the formation of a buried strap on one side using a directional ion beam in line with a first exemplary embodiment according to the invention;

FIGS. 2A-2F are sectional views illustrating the formation of the buried strap on one side using a directional ion beam in line with a second exemplary embodiment according to the invention;

FIGS. 3A and 3B are plan views, on an enlarged scale, of the irradiated bottom of the hole in line with the second exemplary embodiment;

FIGS. 4A-4G are sectional views illustrating the formation of the buried strap on one side using the directional ion beam in line with a third exemplary embodiment according to the invention; and

FIG. 5 is a greatly simplified basic illustration of the apparatus used in line with the invention.

### DESCRIPTION OF THE PREFERRED EMBODIMENTS

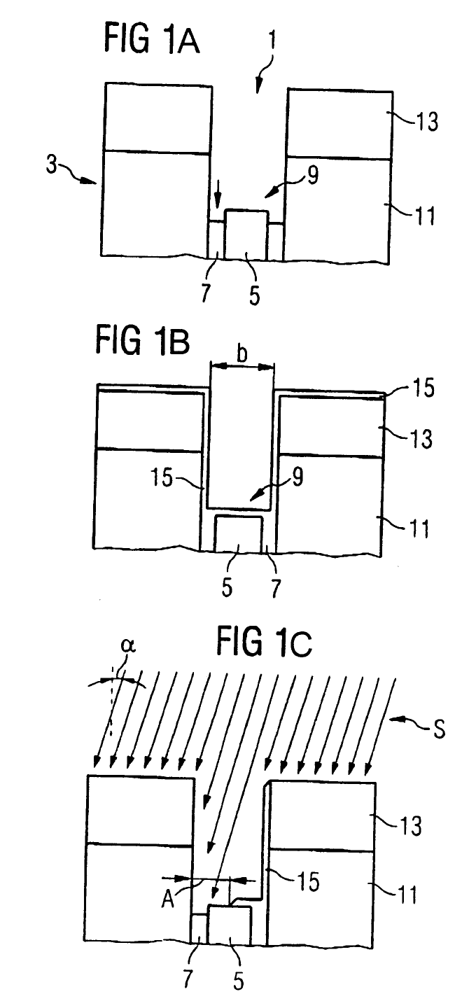

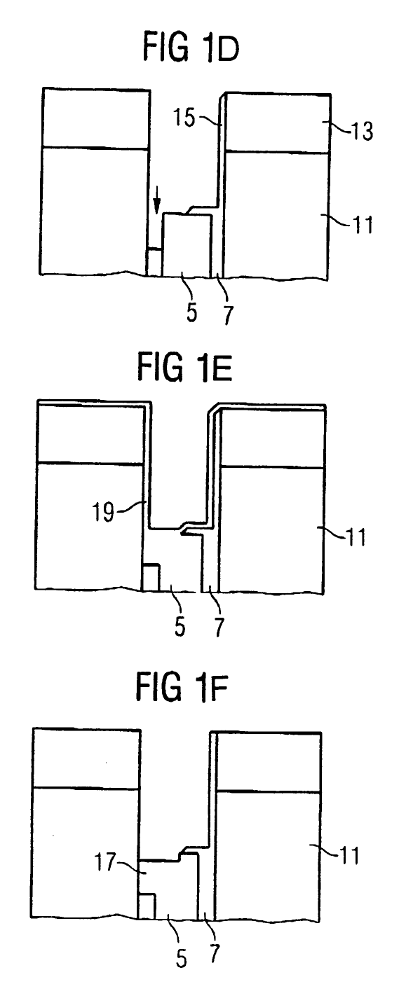

Referring now to the figures of the drawing in detail and first, particularly, to FIG. 1A thereof, there is shown a detail of a DRAM memory cell in a semiconductor circuit which is disposed on a wafer and has been subjected to all the method steps before the start of the inventive method steps (see Widmann, Mader: p. 338; step 9). In this case, for reasons of simplification, FIGS. 1A-1F show just one deep trench (DT) capacitor 1 and an immediately adjoining region of an associated selection transistor 3. The DT capacitor 1 contains a polysilicon core 5, which is surrounded by a core oxide 7, and is disposed in a bottom region of a hole 9 or of a trench having an ellipsoidal base area. The hole 9 is disposed in a silicon substrate 11 which is covered by an Si₃N₄ mask 13 having a thickness of approximately 0.2 μm. In this case, the distance between the top of the Si₃N₄ mask 13 and the top of the polysilicon 5 of the DT capacitor 1 is approximately 0.3-0.4 μm, and the short and long sides of the ellipse are 0.2 and 0.4 μm, respectively. A wet chemical isotropic etching operation has withdrawn the collar oxide 7 somewhat from the top of the polysilicon 5, as shown in FIG. 1A (arrow in FIG. 1A).

In line with FIG. 1B, conformal deposition of a barrier layer, which is suitable as a mask for the subsequent dry or wet etching steps, in the form of an Si₃N₄ liner 15 having a thickness of approximately 5-10 nm is performed. The liner 15 covers, particularly at the circumference too, the side wall of the DT capacitor 1 and the bottom of the hole 9 or the tops of the polysilicon core 5 and the collar oxide 7 (FIG. 1B). An advantage of the choice of material for the liner 15 is that, with Si₃N₄, both Si and SiO₂ can be selectively etched. The thickness of the liner 15 is proportioned, at approximately 5-10 nm, such that the subsequent ion irradiation allows the liner 15 still to be safely removed completely in the irradiated regions and secondly the liner in the regions which are not irradiated and hence are not removed has a sufficiently thick form as a mask for the back etching of the collar oxide 7 which then takes place.

The use of a directional ion beam S, which is directed onto the wafer at an irradiation angle α to the normal (broken line), subjects one side of the DT capacitor 1 in the hole 9 to a much more intense etching or sputtering attack than the side which is in the radiation shadow opposite. As a result, the thin Si₃N₄ barrier layer 15 is removed from the side wall and the bottom of the hole on one side (region A; see FIG. 3A). All the semiconductor structures possibly situated below the thick Si₃N₄ mask 13 are protected from the ion radiation by the mask 13. In the region which is not irradiated and is therefore not removed, the Si₃N₄ liner 15 is a mask, as described below, for the subsequent removal of the collar oxide 7, and therefore a buried strap 17 can be produced only at the points at which the liner 15 has been removed beforehand. In line with FIG. 1C, the irradiation angle α is chosen such that the liner 15 is removed down to half the width b of the hole 9 in the region A. To be able to avoid removal of the Si₃N₄ liner 15 to a disadvantageously minimal or excessive extent, the irradiation angle α is therefore preferably set such that the ion beam S is shielded to approximately ¾ of the hole width b. This ensures that neither too little nor too much Si₃N₄ liner 15 is removed in the bottom region of the hole 9, despite production variations and setting inaccuracies (FIG. 1C, see FIG. 3A).

In a subsequent method step, in line with FIG. 1D, highly selective anisotropic etching (arrow)—with subsequent isotropic over etching to remove residues—is used to back etch the collar oxide 7 on that side of the DT capacitor 1 on which the Si₃N₄ liner 15 has been removed by the ion irradiation beforehand. If the selectivity of the anisotropic etching is not adequate, a bottom liner can also be opened with the liner 15, the bottom liner then again being used as a mask for the subsequent etching step.

In the next method step, in line with FIG. 1E, a polysilicon layer 19 is deposited conformally and hence the conductive connection between the polysilicon core 5 of the DT capacitor 1 and the selection transistor 3 or the silicoon substrate 11 is produced on one side.

To produce the buried strap 17, the polysilicon layer 19 is subsequently subjected to isotropic back etching (FIG. 1F). In the opening produced by the collar oxide back etching in line with FIG. 1D, enough polysilicon remains to form the buried strap 17 (FIG. 1F). Next, following removal of the Si₃N₄ liner 15 still existing on one side, the further process steps required to produce the desired DRAM configuration below the Si₃N₄ mask 13 are carried out. To be able to use just one ion irradiation step at the defined irradiation angle α when removing the Si₃N₄ liner 15 in line with FIG. 1C during production of the buried straps, it is necessary for all the holes 9 in the semiconductor circuit to contain the buried layers 17 on one respective side of the hole 9. This needs to be taken into account as appropriate in the configuration of the individual DRAM cells. In addition, the inventive method is particularly effective when just depressions or holes with a standard geometry are used on the wafer.

In the case of the second exemplary embodiment of the method, wet chemical removal of the collar oxide is used. For reasons of simplification, the description of the method in line with the second exemplary embodiment retains the reference numerals from the first exemplary embodiment. The fundamental advantage of the second method is that it is possible to dispense with the step of wet chemical etching in line with FIG. 1A and hence it is therefore also possible to provide particularly narrow and/or deep holes with buried straps in a suitable manner.

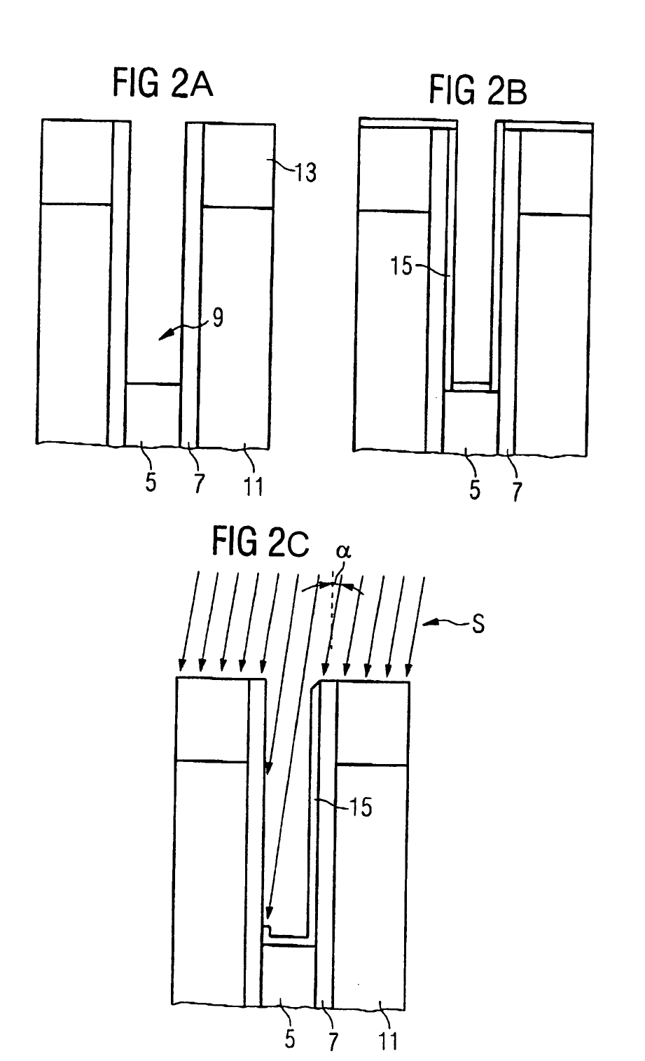

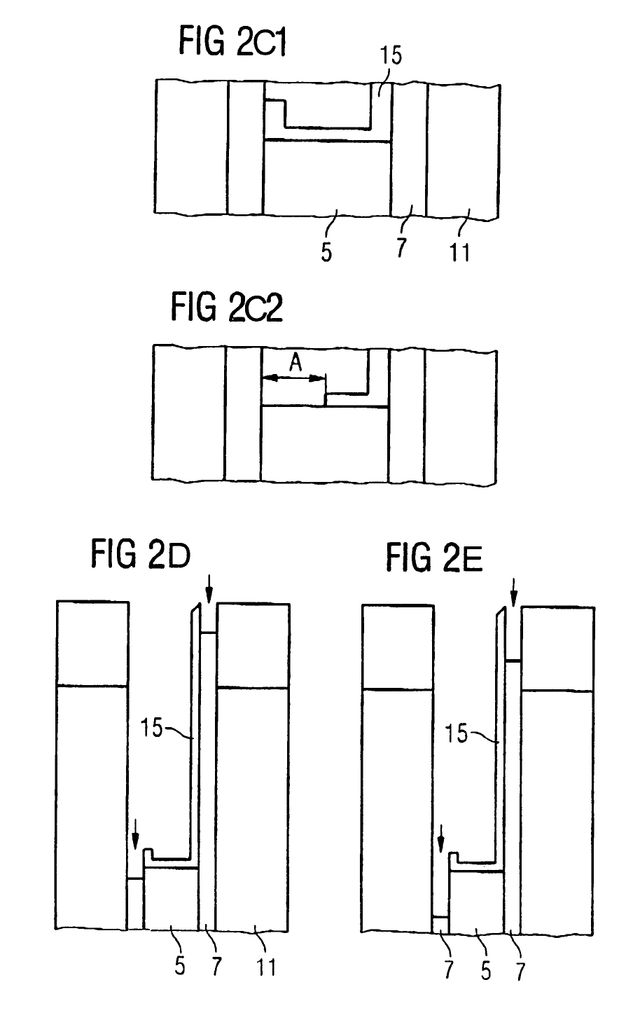

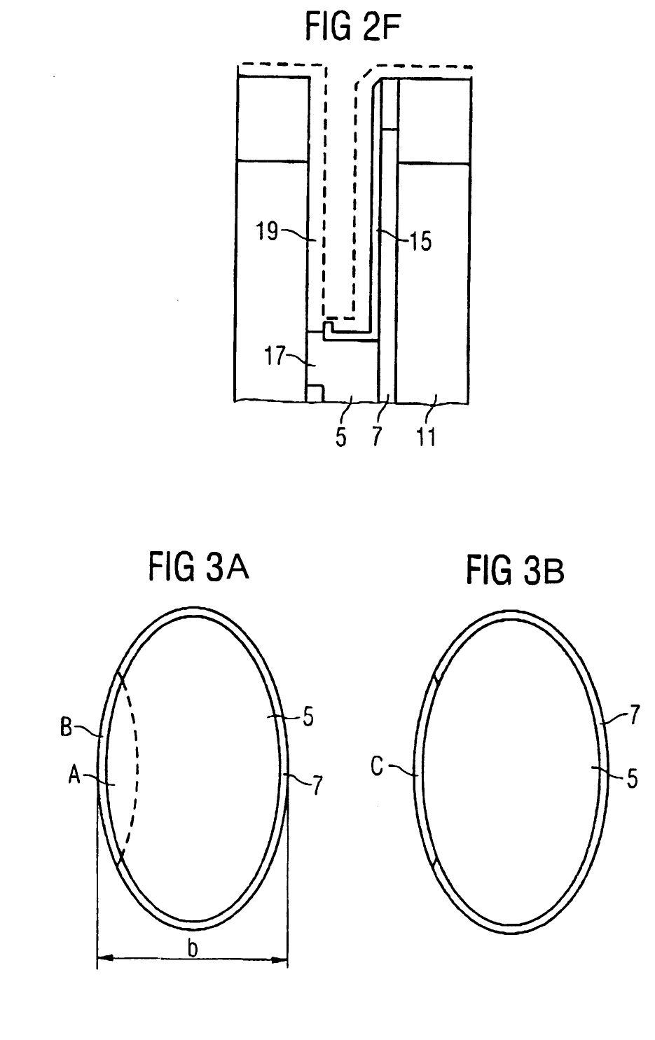

FIG. 2A shows a detail of a DRAM memory cell on the wafer in line with FIG. 1A, the wafer having been subjected to all the method steps before the start of the inventive method steps (see Widmann, Mader: p. 338; step 8). In a clear departure from FIG. 1A, the depth of the hole 9 in this case is approximately 1 μm for a comparable hole base area. The wet chemical back etching of the collar oxide 7 is not performed, in contrast to the first exemplary embodiment.

In the first method step, the Si₃N₄ liner 15 is deposited, conformally. The liner 15 is used as a mask for the subsequent dry or wet etching steps and is likewise approximately 5-10 nm thick. Particularly at the circumference, too, the Si₃N₄ liner 15 covers the sidewall of the DT capacitor 1 or of the collar oxide 7 and the bottom of the hole 9 or the top of the polysilicon core 5 (FIG. 2B).

Next, the liner 15 is removed on one side or on a part of the polysilicon surface 5, in line with the first exemplary embodiment, using the directional ion beam S (FIG. 2C). Limits for the physical extent of the removal of the liner 15 by the ion irradiation which are to be observed in this context are shown in the form of details in FIGS. 2C1 and 2C2. In line with FIG. 2C1, the Si₃N₄ liner 15 remains at most up to a level of the width of the collar oxide 7 (corresponds to the lateral distance between the silicon substrate 11 and the polysilicon core 5) so as still to be in a suitable form for the subsequent etching processes. The other limiting state for removal of the liner 15 results from the fact that, in terms of process technology, it is necessary to ensure that the buried strap 17 is reliably produced just on one side of the DT capacitor 1 (see FIGS. 3A, 3B).

Selective isotropic etching can then be used in the subsequent method step to back etch the collar oxide 7 (arrow), so that the collar oxide 7 is removed completely in the region above the hole bottom on the side wall irradiated beforehand (FIG. 2D).

On this sidewall, the collar oxide 7 is then withdrawn to a sufficient extent using anisotropic back etching (arrow). A further isotropic etching step can subsequently also be used to remove unwanted oxide residues (FIG. 2E).

The deposition of a conformal polysilicon layer 19 (broken line in FIG. 2F) and subsequent isotropic back etching of the deposited poly-Si (FIG. 2F) leaves the gap which has been produced by the collar oxide back etching (FIG. 2E) with sufficient polysilicon to form the buried strap 17 in line with the first exemplary embodiment.

FIGS. 3A and 3B show a plan view, on an enlarged scale, of which region B has the Si₃N₄ liner 15 removed as a result of the ion beam S above the collar oxide 7 in the ellipsoidal hole 9, a bottom area A (FIG. 3A), irradiated by the ion irradiation S, of the DT capacitor 1 and a region C in which the collar oxide 7 has been removed (FIG. 3B) following the double isotropic back etching in line with FIGS. 2D, 2E. FIG. 3A illustrates in which surface region A of the hole bottom, which surface region is bounded essentially ellipsoidally, the ion radiation S appears, which is radiated at the angle α in line with FIG. 2C, and in which remaining surface region the semiconductor configuration is safely shielded by the top edge of the hole 9 in the bottom region. In this context, the radiation component that is reflected into the bottom region from the sidewall of the hole 9 is negligible. In line with FIG. 3B, the isotropic back etching is approximately twice the collar width.

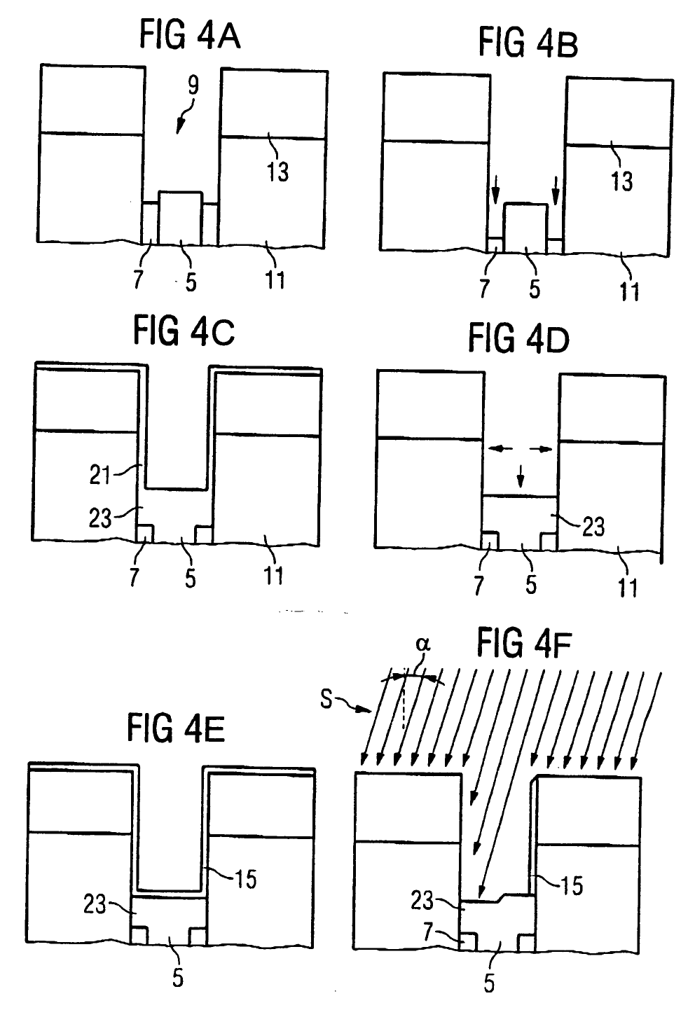

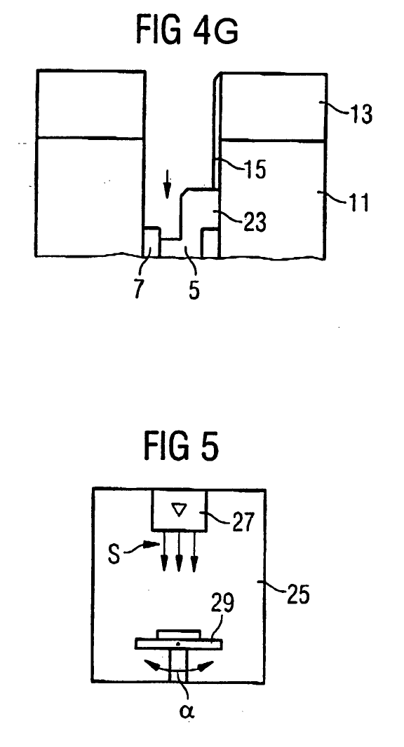

As an alternative to the first two exemplary embodiments, the method in line with the third exemplary embodiment involves removal, on one side, of a conductive connection, initially produced on both sides, between the DT capacitor 1 and the immediately adjoining region of the associated selection transistor 3 and, as a result, production of the buried strap 17 on one side (FIGS. 4A-4G).

Starting from the process situation shown in FIG. 4A, which is identical to that shown in FIG. 1A, the collar oxide 7 is isotropically back etched (arrow in FIG. 4B). In the subsequent process step, a conformal polysilicon layer 21 is deposited (FIG. 4C) which, at the circumference or on both sides, produces the contact between the polysilicon core 5 and the silicon substrate 11 in the region of the bottom of the hole as a polysilicon ring 23. The polysilicon layer 21 is then subjected to isotropic back etching and as a result is also removed above the polysilicon core 5 on the side wall of the hole 9 (arrows in FIG. 4D). In line with FIG. 4E, a conformal Si₃N₄ liner 15 is then deposited. Next, the liner 15 is removed (FIG. 4F) using an obliquely directed ion beam S on one side of the side wall of the hole 9 and on a part of the surface of the polysilicon core 5 or the polysilicon ring 23 in line with the first two exemplary embodiments (step in FIGS. 1C and 2C). Anisotropic selective back etching (arrow) of the polysilicon down to the top of the buried collar oxide 7 safely removes the conductive connection between the polysilicon core 5 and the silicon substrate 11 on one side (FIG. 4G). The Si₃N₄ liner 15 can then be removed in an isotropic etching step, and the hole 9 or the depression can be filled with SiO₂, for example (not shown).

It is obvious that the geometries of the holes in the semiconductor configuration, such as hole shape and depth, can be changed without departing from the disclosure of the invention.

A prerequisite for carrying out the inventive method is suitable generation of a directional ion beam. This can be produced, by way of example, by an ion beam etching (IBE), chemically assisted ion beam etching (CAIBE) or reactive ion beam etching (RIBE) source. In this case, the ion source is tilted from the normal orientation through the irradiation angle α relative to the wafer. The angle α is calculated from the geometry of the holes in the semiconductor configuration and is optimized in trials. The necessary irradiation systems are commercially available from various manufacturers, in some cases with beam diameters for whole-wafer processing as well.

In addition, it is possible to use an implantation system with noble gas ions, for example, in order to order to carry out the inventive method. An alternative possibility is suitable modification of an RIE system, with the ions being deflected in a suitable manner. The etching method using directional atom beams (neutral stream etch (NSE)) can also be used to implement the invention.

FIG. 5 shows a simplified form of the inherently known apparatus for carrying out the inventive method. In this case, a vacuum chamber 25 contains an ion source 27 and a pivotable sample table 29 on which the wafer is disposed for irradiation at the irradiation angle α.

We claim:

1. A method for producing a buried strap contact in a trench capacitor having a polysilicon core and a collar oxide surrounding the polysilicon core, which comprises the steps of:
providing a silicon substrate having a depression formed therein, the trench capacitor with the polysilicon core and the collar oxide being disposed in the depression;
introducing a mask layer into the depression;
patterning the mask layer with an ion beam being directed obliquely onto the depression at an angle for irradiating the mask layer only in an irradiated subregion of the depression resulting in a removal of the mask layer in the irradiated subregion, the collar oxide being partially exposed during the irradiating;
back etching exposed areas of the collar oxide along the polysilicon core using the mask layer as an etching mask resulting in a back etched collar oxide; and
forming a polysilicon layer in a region of the back etched collar oxide to produce the buried strap contact for the polysilicon core of the trench capacitor.

2. The method according to claim 1, which further comprises etching away part of the collar oxide from a top of the polysilicon core in the depression before performing the introducing step.

3. The method according to claim 1, which further comprises:
forming the mask layer with a top liner layer and a bottom liner layer, and the ion beam patterning the top liner layer; and
transferring a pattern of the top liner layer to the bottom liner layer with an etching process.

4. The method according to claim 1, which further comprises forming the collar oxide to cover sidewalls of the depression and the ion beam patterns the mask layer such that the mask layer is removed on a side wall of the depression at least down to a level above a top of the polysilicon core which corresponds to a width of the collar oxide.

5. The method according to claim 1, which further comprises depositing an Si₃N₄ layer having a thickness of approximately 5-10 nm into the depression for forming the mask layer to be patterned by the ion beam.

6. The method according to claim 1, which further comprises generating the ion beam with a reactive ion beam etching source.

7. A method for producing a buried strap contact for a trench capacitor having a polysilicon core and a core oxide surrounding the polysilicon core, which comprises the steps of:
providing a silicon substrate having a depression formed therein, the trench capacitor with the polysilicon core and the collar oxide being disposed in the depression;
etching back the collar oxide along the polysilicon core;
forming a polysilicon layer on a bottom of the depression;
introducing a mask layer into the depression;
patterning the mask layer with an ion beam being directed obliquely onto the depression at an angle for irradiating the mask layer only in an irradiated subregion of the depression for removing the mask layer in the irradiated subregion, the polysilicon layer being partially exposed during the irradiating resulting in an exposed polysilicon layer;
back etching the exposed polysilicon layer down to the collar oxide using the mask layer as an etching mask to define the buried strap contact for the polysilicon core of the trench capacitor in a region of a remaining polysilicon layer; and
filling the depression with an oxide layer.

8. The method according to claim 7, which further comprises etching the collar oxide for removing the collar oxide from a top of the polysilicon core.

9. The method according to claim 7, which further comprises providing the silicon substrate with a plurality of depressions formed therein all having a standard geometry.

10. The method according to claim 7, which further comprises depositing an Si₃N₄ layer having a thickness of approximately 5-10 nm into the depression for forming the mask layer to be patterned by the ion beam.

11. The method according to claim 7, which further comprises generating the ion beam with a reactive ion beam etching source.
